(19) United States
(12) Patent Application Publication
(10) Pub. No.: US 2026/0186415 A1
(43) Pub. Date: Jul. 2, 2026

(54) POLYMER, POSITIVE PHOTORESIST COMPOSITION, AND METHOD FOR FORMING PATTERNED PHOTORESIST LAYER

(71) Applicant: INDUSTRIAL TECHNOLOGY RESEARCH INSTITUTE, Hsinchu (TW)

(72) Inventors: Yu-Ying HSU, Hsinchu City (TW); Te-Yi CHANG, Taoyuan City (TW); Yao-Jheng HUANG, Taipei City (TW); Yi-Chin LIU, Taichung City (TW)

(73) Assignee: INDUSTRIAL TECHNOLOGY RESEARCH INSTITUTE, Hsinchu (TW)

(21) Appl. No.: 19/004,749

(22) Filed: Dec. 30, 2024

(51) Int. Cl. G03F 7/039; G03F 7/004; G03F 7/32; G03F 7/38

(52) U.S. Cl. CPC G03F 7/039; G03F 7/0045; G03F 7/322; G03F 7/38

(57) ABSTRACT

A polymer, positive photoresist composition, and method for forming patterned photoresist layer are provided. The polymer includes a first repeating unit and a second repeating unit. The first repeating unit has a structure of Formula (I) and the second repeating unit has a structure of Formula (II)

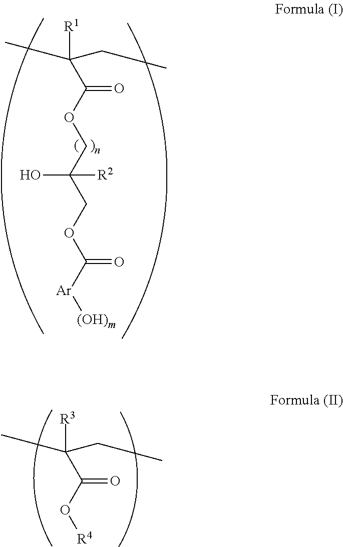

wherein R¹, R², R³, R⁴, Ar, n, and m are as defined in the specification.

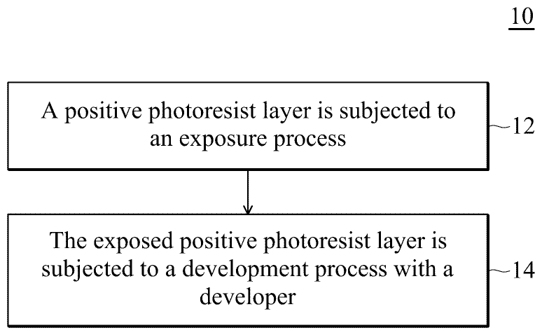

### TECHNICAL FIELD

The disclosure relates to a polymer, positive photoresist composition, and method for forming patterned photoresist layer.

### BACKGROUND

With the continuous advancements being made in the fields of integrated circuit manufacturing and packaging technologies, printed circuit boards (PCBs) have been developed to achieve high-density wiring, miniaturization, high electrical properties, high dimensional stability, high resolution, and cost reduction. Additionally, there is an increasing demand for multilayer technology with smaller pore sizes and higher alignment accuracy.

In the process of manufacturing printed circuit boards, achieving high-density wiring and high resolution requires further reductions in the width or line pitch (10 μm or less) of the photosensitive patterned photoresist layer that is formed. Furthermore, it is also important to reduce the manufacturing cost of the photoresist layer (e.g., by using a mildly alkaline developer, e.g., a 1% sodium carbonate aqueous solution). Therefore, a photosensitive photoresist material that enables near-ultraviolet exposure, development with a weakly alkaline developer, high resolution, and low cost is highly desirable.

Although liquid photoresist compositions can form photosensitive photoresist patterns with better resolution, the manufacturing process becomes more complex as the substrate size increases. In addition, since liquid photoresist compositions cannot be dissolved in weak alkaline solutions (such as a 1% sodium carbonate aqueous solution), liquid photoresist compositions are difficult to apply in PCB manufacturing processes.

Therefore, there is still a need in the industry for a high-performance photoresist composition suitable for high-resolution printed circuit board manufacturing.

### SUMMARY

The disclosure provides a polymer. According to embodiments of the disclosure, the polymer includes a first repeating unit and a second repeating unit. the first repeating unit has a structure of Formula (I) and the second repeating unit has a structure of Formula (II)

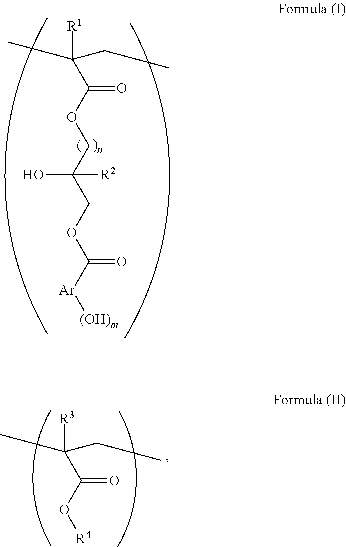

wherein R¹, R² and R³ are independently hydrogen or C1-C4 alkyl group; R⁴ is branched C4-C10 alkyl group, C5-C10 cycloalkyl group, or substituted C5-C10 cycloalkyl group; Ar is C6-C12 aryl group, or C7-C18 alkyl aryl group, wherein m number of hydrogen bonded with carbon of Ar is substituted by hydroxyl group; n is 0, 1, 2, 3, or 4; and m is 1, 2, or 3.

The disclosure provides a positive photoresist composition, which is used for preparing a patterned photoresist layer. According to embodiments of the disclosure, the positive photoresist composition includes the polymer of the disclosure and a photoacid generator.

The disclosure provides a method for forming a patterned photoresist layer. According to embodiments of the disclosure, the method includes the following steps. A positive photoresist layer is subjected to an exposure process, wherein the positive photoresist layer is obtained by drying the positive photoresist composition of the disclosure. In addition, the positive photoresist layer is subjected to a development process with a developer, obtaining the patterned photoresist layer of the disclosure.

A detailed description is given in the following embodiments.

### BRIEF DESCRIPTION OF THE DRAWINGS

The present disclosure can be more fully understood by reading the subsequent detailed description and examples with references made to the accompanying drawing, wherein:

FIGURE is a flow chart illustrating the method for forming a patterned photoresist layer according to an embodiment of the disclosure.

### DETAILED DESCRIPTION

The polymer, positive photoresist composition, and method for forming a patterned photoresist layer are described in detail in the following description. In the following detailed description, for purposes of explanation, numerous specific details and embodiments are set forth in order to provide a thorough understanding of the present disclosure. The specific elements and configurations described in the following detailed description are set forth in order to clearly describe the present disclosure. It will be apparent, however, that the exemplary embodiments set forth herein are used merely for the purpose of illustration, and the inventive concept may be embodied in various forms without being limited to those exemplary embodiments. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments. As used herein, the term “about” in quantitative terms refers to plus or minus an amount that is general and reasonable to persons skilled in the art.

Furthermore, the use of ordinal terms such as “first”, “second”, “third”, etc., in the disclosure to modify an element does not by itself connote any priority, precedence, order of one claim element over another or the temporal order in which it is formed, but are used merely as labels to distinguish one claim element having a certain name from another element having the same name (but for use of the ordinal term) to distinguish the claim elements.

The disclosure provides a polymer, a positive photoresist composition employing the same, and a method for forming a patterned photoresist layer. Since the polymer of the disclosure has alkali-soluble properties (such as being soluble in sodium carbonate (Na₂CO₃) aqueous solution), it can be applied to positive photoresist composition for preparing a high resolution photosensitive positive dry film materials (such as forming patterns with line width≤10 μm). Since the positive photoresist composition of the disclosure and the dry film prepared therefrom have good light sensitivity and light transmittance, enabling the achievement of high clarity and high precision wiring patterns. Furthermore, due to the close adhesion with the substrate during pattern formation, the patterned photoresist layer exhibits superior peeling property from the substrate, thereby simplifying the process of forming wiring patterns. In addition, in comparison with the conventional photosensitive phenol resin composition, the positive photoresist composition including the polymer of the disclosure can be developed in sodium carbonate (Na₂CO₃) aqueous solution, and is very suitable for use in the process of printed circuit board (such as high resolution printed circuit board).

According to embodiments of the disclosure, the polymer may include a first repeating unit and a second repeating unit, wherein the first repeating unit has a structure of Formula (I), and the second repeating unit has a structure of Formula (II)

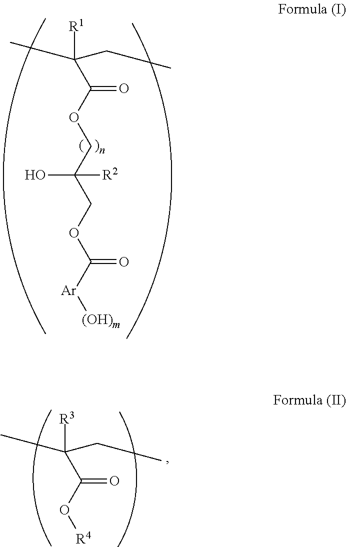

wherein R¹, R² and R³ are independently hydrogen or C1-C4 alkyl group; R⁴ is branched C4-C10 alkyl group, C5-C10 cycloalkyl group, or substituted C5-C10 cycloalkyl group; Ar is C6-C12 aryl group, or C7-C18 alkyl aryl group, wherein m number of hydrogen bonded with carbon of Ar is substituted by hydroxyl group; n is 0, 1, 2, 3, or 4; and m is 1, 2, or 3. According to embodiments of the disclosure, R⁴ is bonded to oxygen through a tertiary carbon atom.

According to embodiments of the disclosure, C1-C4 alkyl group may be a linear or branched alkyl group. For example, C1-C4 alkyl group may be methyl, ethyl, n-propyl, isopropyl, n-butyl, sec-butyl, iso-butyl, or tert-butyl. According to embodiments of the disclosure, branched C4-C10 alkyl group refers to C4-C10 alkyl group containing a tertiary carbon atom, wherein a tertiary carbon is a carbon atom bonded to three other carbon atoms. For example, branched C4-C10 alkyl group may be tert-butyl, tert-pentyl, or tert-hexyl.

According to embodiments of the disclosure, C5-C10 cycloalkyl group may be a mono-cycloalkyl group or a polycycloalkyl group (such as a bicycloalkyl group or a tricycloalkyl group). A polycycloalkyl group may have a fused ring, bridged ring, or spiro ring system. For example, C5-C10 cycloalkyl group may be cyclopentyl, cyclohexyl, cycloheptyl, cyclooctyl, adamantyl, or norbornenyl. According to embodiments of the disclosure, substituted C5-C10 cycloalkyl group refers to C5-C10 cycloalkyl group in which at least one of the hydrogen bonded with the carbon can optionally be replaced with C1-C4 alkyl group or hydroxyl group.

According to embodiments of the disclosure, the polymer may include at least one type of first repeating unit and at least one type of second repeating unit. Namely, the polymer may include at least one repeating unit having a structure represented by Formula (I) and at least one repeating unit having a structure represented by Formula (II).

According to embodiments of the disclosure, the first repeating unit may be

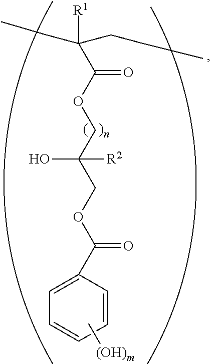

wherein R¹, R², n and m are the same as defined above.

According to embodiments of the disclosure, the first repeating unit may be

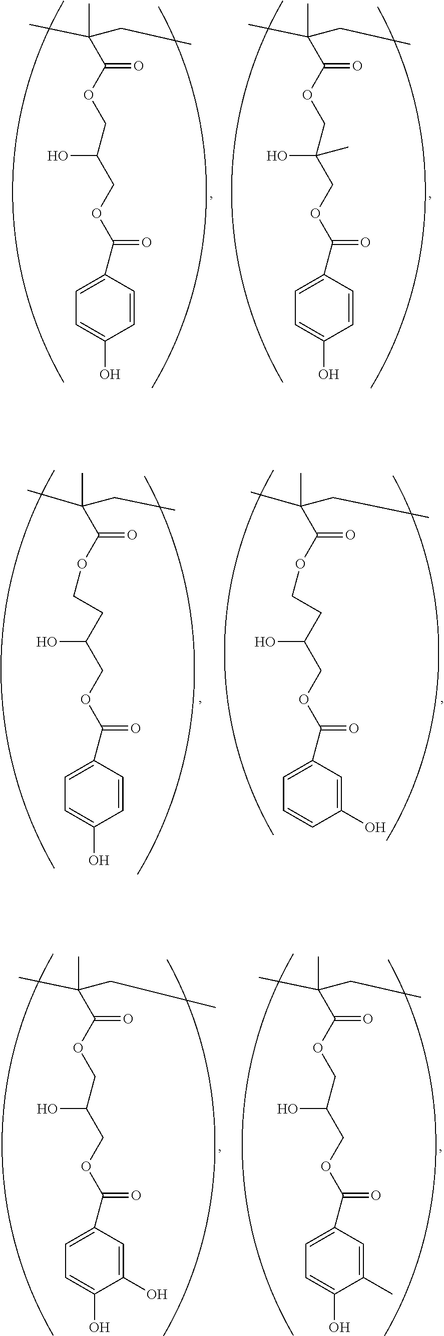

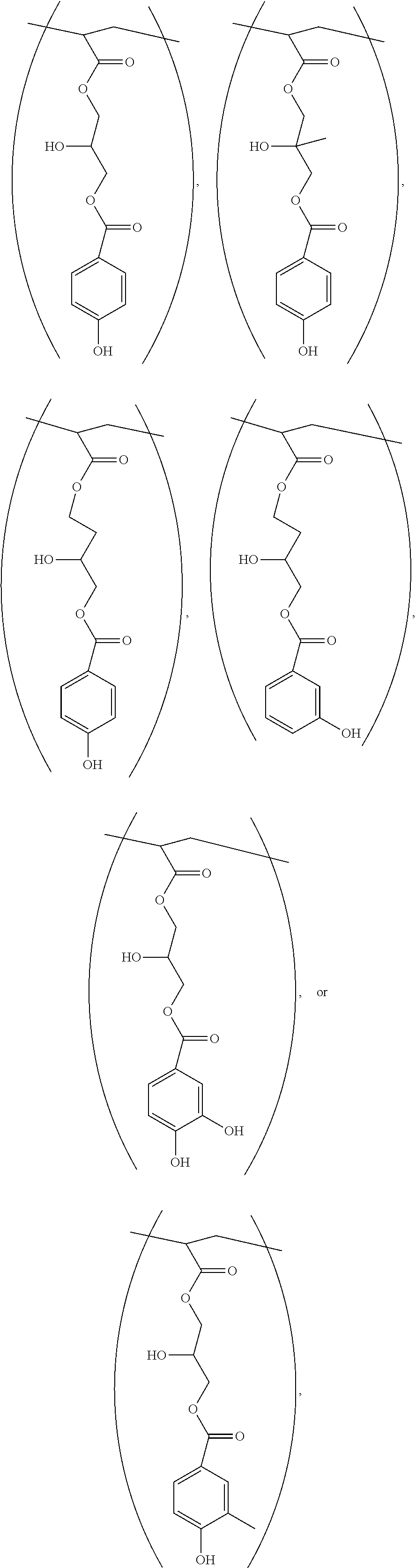

According to embodiments of the disclosure, the second repeating unit may be

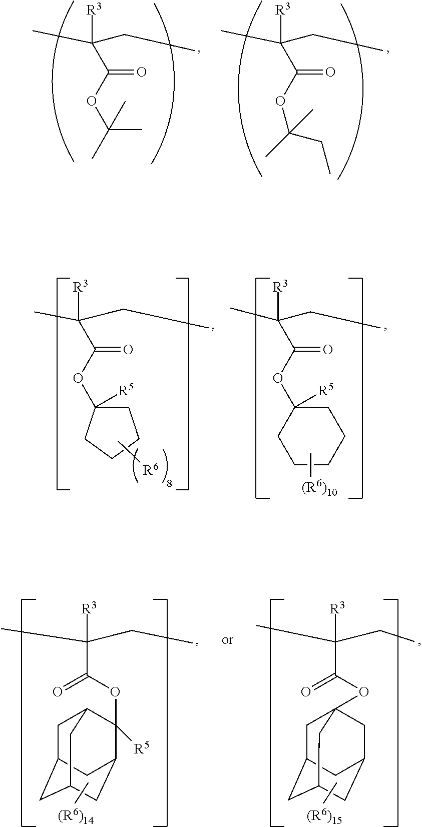

wherein R³ is hydrogen or C1-C4 alkyl group; R⁵ is C1-C4 alkyl group; and R⁶ is independently hydrogen, C1-C4 alkyl group, or hydroxyl group. For example, the second repeating unit may be

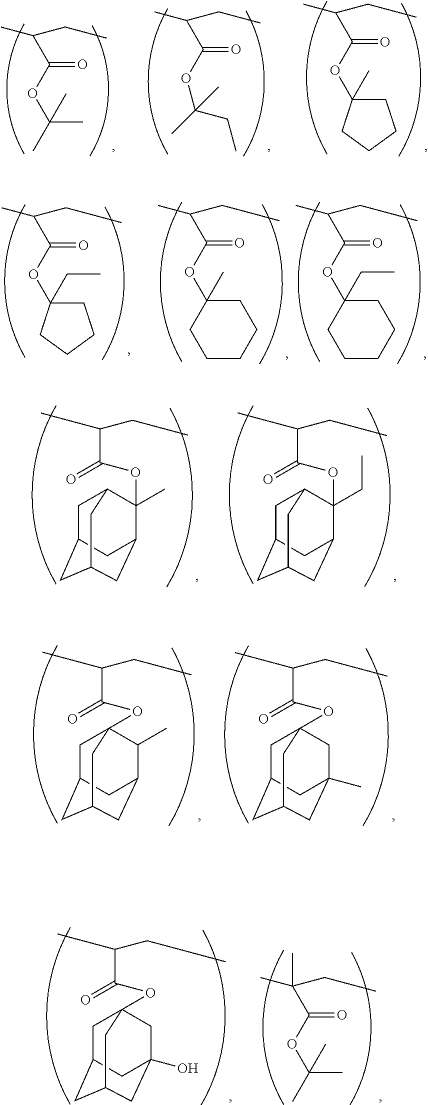

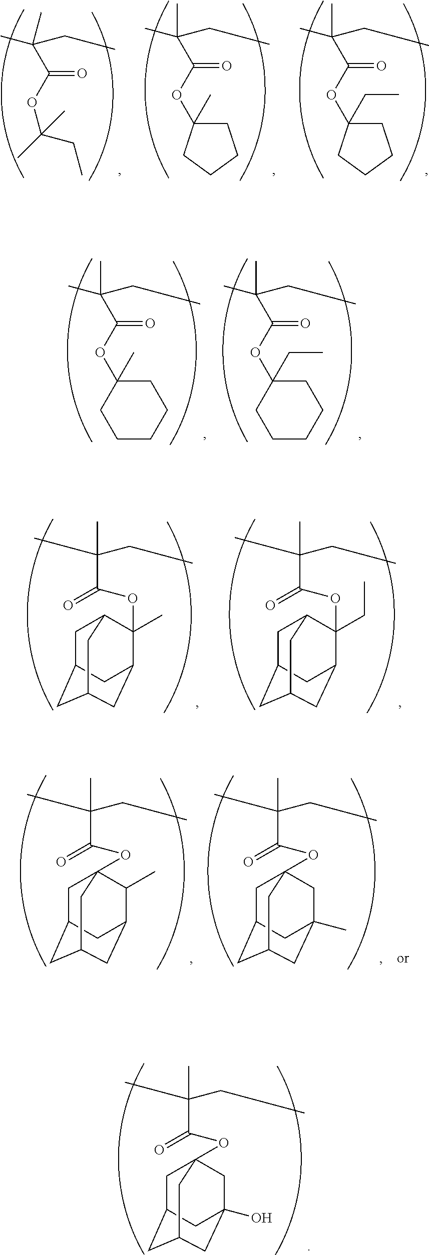

According to embodiments of the disclosure, the polymer may consist of the first repeating unit and the second repeating unit. According to embodiments of the disclosure, the polymer, except for the first repeating unit and the second repeating unit, does not include any other repeating units.

According to embodiments of the disclosure, the first repeating unit and the second repeating unit may be arranged in a random or block fashion.

According to embodiments of the disclosure, in the polymer of the disclosure, the number ratio of the first repeating unit to the second repeating unit may be 100:20 to 100:150, such as 100:25, 100:30, 100:40, 100:50, 100:60, 100:70, 100:80, 100:90, 100:100, 100:110, 100:120, 100:130, or 100:140. As a result, the positive photoresist composition including the polymer of the disclosure can be developed using a weakly alkaline developer (such as sodium carbonate aqueous solution) after exposure, resulting in a pattern with excellent resolution.

According to embodiments of the disclosure, the polymer of the disclosure further includes a third repeating unit, wherein the third repeating unit has a structure of Formula (III)

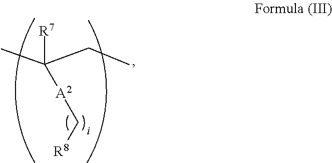

wherein R⁷ is hydrogen or C1-C4 alkyl group; A² is a single bond, or

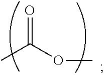

R⁸ is C6-C12 aryl group, or substituted C6-C12 aryl group; and i is 0, 1, 2, 3, or 4. According to embodiments of the disclosure, substituted C6-C12 aryl group refers to C6-C12 aryl group in which at least one of the hydrogen atom bonded with the carbon can optionally be replaced with C1-C4 alkyl group.

According to embodiments of the disclosure, the third repeating unit may be

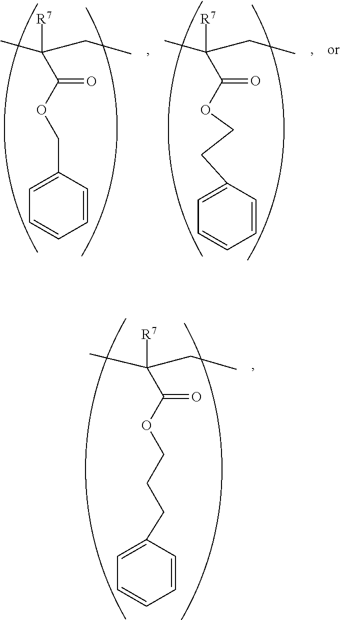

wherein R⁷ is hydrogen or C1-C4 alkyl group.

According to embodiments of the disclosure, the third repeating unit may be

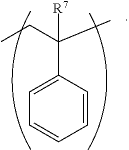

According to embodiments of the disclosure, in the polymer of the disclosure, the number ratio of the first repeating unit to the third repeating unit may be 100:1 to 100:50, such as 100:2, 100:3, 100:5, 100:10, 100:20, 100:30, or 100:40. As a result, the positive photoresist composition including the polymer of the disclosure can be developed using a weakly alkaline developer (such as sodium carbonate aqueous solution) after exposure.

According to embodiments of the disclosure, the polymer may consist of the first repeating unit and the second repeating unit. According to embodiments of the disclosure, the polymer, except for the first repeating unit and the second repeating unit, does not include any other repeating units.

According to embodiments of the disclosure, except for the first repeating unit, second repeating unit, and third repeating unit, if the polymer of the disclosure further includes other repeating units, the ratio of the total number of the first, second, and third repeating units to the total number of all repeating units is 90:100 to 99.9:100.

According to embodiments of the disclosure, the weight average molecular weight of the polymer of the disclosure may be 14,000 g/mol to 100,000 g/mol, such as 15,000 g/mol, 18,000 g/mol, 20,000 g/mol, 25,000 g/mol, 30,000 g/mol, 35,000 g/mol, 40,000 g/mol, 45,000 g/mol, 50,000 g/mol, 55,000 g/mol, 60,000 g/mol, 65,000 g/mol, 70,000 g/mol, 75,000 g/mol, 80,000 g/mol, 85,000 g/mol, 90,000 g/mol, or 95,000 g/mol. The weight average molecular weight (Mw) of the polymer of the disclosure can be determined by gel permeation chromatography (GPC) based on a polystyrene calibration curve. When the molecular weight of the polymer is too low, the pattern with a narrower width (10 μm or less) formed by the positive photoresist composition including the polymer of the disclosure exhibits poor adhesion, making it difficult to form a high-resolution pattern layer. When the molecular weight of the polymer is too high, the positive photoresist composition including the polymer of the disclosure becomes less soluble in a weakly alkaline developer after exposure.

The polymer of the disclosure can be obtained by polymerization of a first monomer and a second monomer. In the polymer of the disclosure, the first repeating unit is derived from the first monomer, and the second repeating unit is derived from the second monomer.

According to embodiments of the disclosure, the first monomer may be

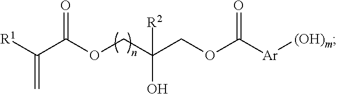

the second monomer may be

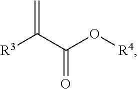

wherein R¹, R², R³, R⁴, Ar, n, and m are the same as defined above.

According to embodiments of the disclosure, the first monomer may be

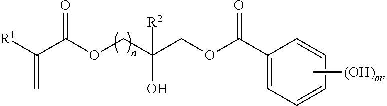

wherein R¹, R², n, and m are the same as defined above.

According to embodiments of the disclosure, when the polymer of the disclosure is obtained by polymerization of the first monomer and the second monomer, the molar ratio of the first monomer to the second monomer may be 100:10 to 100:150, such as 100:10, 100:20, 100:30, 100:40, 100:50, 100:60, 100:70, 100:80, 100:90, 100:100, 100:110, 100:120, 100:130, or 100:140.

The polymer of the disclosure can be obtained by polymerization of a first monomer, a second monomer and a third monomer. In the polymer of the disclosure, the first repeating unit is derived from the first monomer, the second repeating unit is derived from the second monomer, and the third repeating unit is derived from the third monomer.

According to embodiments of the disclosure, the third monomer may be

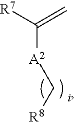

For example, the third monomer may be

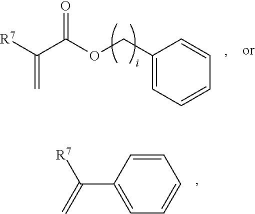

wherein R⁷ is hydrogen or C1-C4 alkyl group.

According to embodiments of the disclosure, when the polymer of the disclosure is obtained by polymerization of the first monomer, the second monomer and the third monomer, the molar ratio of the first monomer to the third monomer may be 100:10 to 100:150, such as 100:10, 100:20, 100:30, 100:40, 100:50, 100:60, 100:70, 100:80, 100:90, 100:100, 100:110, 100:120, 100:130, or 100:140.

The method for preparing the polymer of the disclosure is not particularly limited. For example, the first monomer and the second monomer may be mixed (or a third monomer may be further added) and subjected to copolymerization in the presence of a chain transfer agent and/or catalyst (the reaction temperature may range from 50° C. to 150° C., and the reaction time may range from 1 hour to 12 hours). According to embodiments of the disclosure, the molecular weight of the polymer of the disclosure can be controlled by adjusting the amount of chain transfer agent and/or catalyst, the reaction temperature, and the reaction time. According to embodiments of the disclosure, the first monomer may first undergo homopolymerization to obtain a first oligomer, the second monomer may first undergo homopolymerization to obtain a second oligomer, and/or the third monomer may first undergo homopolymerization to obtain a third oligomer. The resulting oligomers are then mixed with other monomers or oligomers and copolymerized in the presence of a chain transfer agent and/or catalyst. According to embodiments of the disclosure, the chain transfer agent and catalyst are not particularly limited and may be conventional chain transfer agents and catalysts used in copolymerization.

According to embodiments of the disclosure, the disclosure also provides a positive photoresist composition. The positive photoresist composition may include the polymer of the disclosure, and a photoacid generator.

According to embodiments of the disclosure, the positive photoresist composition of the disclosure exhibits high photosensitivity and high light transmittance. As a result, the dry film prepared from the positive photoresist composition of the disclosure can achieve high clarity and high precision in wiring patterns.

According to embodiments of the disclosure, the weight ratio of the photoacid generator to the polymer may be from 0.5:100 to 20:100, such as 8:100, 10:100, 15:100, or 20:100.

According to embodiments of the disclosure, the photoacid generator may be an onium salt, triarylsulfonium salt, alkylarylsulfonium salt, diaryliodonium salt, diarylchloronium salt, diarylbromonium salt, sulfonate salt, sulfonate ester, fluorosulfonate ester, diazonium salt, diazonaphthoquinone sulfonate, or a combination thereof.

According to embodiments of the disclosure, in the positive photoresist composition of the disclosure, the polymer of the disclosure and the photoacid generator may be uniformly dissolved in an organic solvent.

According to embodiments of the disclosure, the organic solvent may be benzene, toluene, xylene, ethylbenzene, diethylbenzene, trimethylbenzene, triethylbenzene, cyclohexane, cyclohexene, decahydronaphthalene, dipentene, pentane, hexane, heptane, octane, nonane, decane, ethyl cyclohexane, methyl cyclohexane, p-menthane, dipropyl ether, dibutyl ether, anisole, ethyl acetate, butyl acetate, pentyl acetate, methyl isobutyl ketone (MEK), cyclohexylbenzene, cyclohexanone, cyclopentanone (CPN), triglyme, 1,3-dimethyl-2-imidazolidinone (DMI), N-methyl-2-pyrrolidone (NMP), methyl ethyl ketone (MEK), N,N-dimethylacetamide (DMAc), γ-butyrolactone (GBL), N,N-dimethylformamide (DMF), propylene glycol methyl ether acetate (PGMEA), dimethyl sulfoxide (DMSO), or a combination thereof.

According to embodiments of the disclosure, in order to achieve the appropriate properties for the positive photoresist composition or the dry film formed from it, one or more additives may be optionally added as needed, such as inhibitor, leveling agent, colorant, adhesion promoter, thixotropic agent, sensitizer, filler, and the like. According to embodiments of the disclosure, the amount of additive may range from 0.1 wt % to 30 wt %, based on the total weight of the polymer and the photoacid generator.

According to embodiments of the disclosure, when the positive photoresist composition of the disclosure includes an organic solvent, the solid content of the positive photoresist composition may be about 10% to 50% (such as 15%, 20%, 25%, 30%, 35%, 40%, or 45%). The solid content refers to the weight percentage of all components in the composition except for the organic solvent, based on the total weight of the composition.

The disclosure also provides a method for forming a patterned photoresist layer. As shown in FIGURE, the method for forming the patterned photoresist layer 10 includes the following steps. A positive photoresist layer is subjected to an exposure process (step 12), wherein the positive photoresist layer is obtained by drying the positive photoresist composition of the disclosure. Next, the positive photoresist layer is subjected to a development process with a developer after exposure (step 14), obtaining a patterned photoresist layer of the disclosure.

According to embodiments of the disclosure, the light source for the exposure process may be ultraviolet (UV) light (with a wavelength of 150 nm to 450 nm), and the exposure dose may range from 10 mJ/cm² to 500 mJ/cm² (such as 20 mJ/cm², 50 mJ/cm², 70 mJ/cm², 100 mJ/cm², 120 mJ/cm², 150 mJ/cm², 200 mJ/cm², 250 mJ/cm², 300 mJ/cm², 350 mJ/cm², 400 mJ/cm², or 450 mJ/cm²).

According to embodiments of the disclosure, the developer may be an alkali metal salt aqueous solution, such as a sodium carbonate aqueous solution or a potassium carbonate aqueous solution. According to embodiments of the disclosure, the alkali salt content in the alkali metal salt aqueous solution may be 0.1 wt % to 5 wt %, based on the total weight of the alkali metal salt aqueous solution.

According to embodiments of the disclosure, the positive photoresist layer may be a dry film obtained by coating the positive photoresist composition of the disclosure and drying it.

According to embodiments of the disclosure, the method for preparing the positive photoresist dry film and its usage may include the following steps. First, a solution of the positive photoresist composition is coated onto a carrier film. After drying, a protective film is attached to the dried photoresist composition, thus forming the positive photoresist dry film. During transfer printing, the protective film is peeled off, and the dried photoresist composition is transferred onto a substrate by a transfer printing process. Then, the carrier film is peeled off, and exposure and development processes are performed.

The coating methods for the positive photoresist composition are not limited and may include screen printing, spin coating, bar coating, blade coating, roller coating, dip coating, spray coating, or brush coating.

According to embodiments of the disclosure, the carrier film and protective film may be polyethylene terephthalate (PET) film, polyethylene (PE) film, or oriented polypropylene (OPP) film. According to embodiments of the disclosure, the substrate may be a wafer or a copper-clad laminate.

Below, exemplary embodiments will be described in detail so as to be easily realized by a person having ordinary knowledge in the art. The inventive concept may be embodied in various forms without being limited to the exemplary embodiments set forth herein.

### Preparation of Monomer

### Preparation Example 1

Glycidyl methacrylate (GMA) (375 g), 4-hydroxybenzoic acid (367.5 g), catalyst (triphenylphosphine) (1.88 g), and inhibitor (hydroquinone) (1.05 g) were added into a solvent (1-methoxy-2-propanol acetate, PGMEA) (320 g), obtaining a mixture. The mixture was stirred at 100° C. for 4 hours. After purification, Monomer (I) (having a structure of

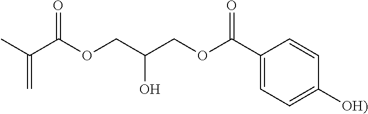

was obtained.

### Preparation of Polymer

### Preparation Examples 2-8

Monomer (I), styrene, tert-butyl acrylate, catalyst (2,2′-azobis(2-methylpropionitrile, AIBN), chain transfer agent (1-dodecanethiol), and solvent (1-methoxy-2-propanol acetate, PGMEA) were mixed according to the proportions described in Table 1. The results were heated and stirred (with a reaction temperature and time as shown in Table 1), obtaining Polymers (1)-(7). The weight average molecular weight (Mw) of Polymers (1)-(7) was determined by gel permeation chromatography (GPC), and the results are shown in Table 1.

TABLE 1

| | Preparation | Preparation | Preparation | Preparation | Preparation | Preparation | Preparation |
|---|---|---|---|---|---|---|---|
| | Example | Example | Example | Example | Example | Example | Example |
| | 2_Polymer | 3_Polymer | 4_Polymer | 5_Polymer | 6_Polymer | 7_Polymer | 8_Polymer |
| | (1) | (2) | (3) | (4) | (5) | (6) | (7) |
| Monomer | 7:3 | 3:1 | 6:1 | 5:3 | 9:4 | 8:5 | 14:3 |
| (I):styrene | | | | | | | |
| (molar | | | | | | | |
| ratio) | | | | | | | |
| Monomer | 7:3 | 3:1 | 2:1 | 5:2 | 9:7 | 8:7 | 14:3 |
| (I):tert- | | | | | | | |
| butyl | | | | | | | |
| acrylate | | | | | | | |
| (molar | | | | | | | |
| ratio) | | | | | | | |
| total weight | 230.8 | 214.4 | 216.9 | 196.8 | 191.6 | 182.8 | 230.8 |
| of | | | | | | | |
| Monomer | | | | | | | |
| (I), styrene, | | | | | | | |
| tert-butyl | | | | | | | |
| acrylate (g) | | | | | | | |
| catalyst (g) | 6 | 6 | 6 | 6 | 6 | 6 | 3 |
| chain | 12 | 12 | 12 | 12 | 12 | 12 | 3 |
| transfer | | | | | | | |
| agent (g) | | | | | | | |
| solvent (g) | 276 | 282 | 275 | 250 | 252 | 252 | 265 |
| reaction | 90 | 90 | 90 | 90 | 90 | 90 | 90 |
| temperature | | | | | | | |
| (° C.) | | | | | | | |
| reaction | 6 | 6 | 6 | 6 | 6 | 6 | 6 |
| time (hours) | | | | | | | |
| weight | 24,000 | 13,111 | 8,500 | 9,481 | 7,415 | 6,857 | 66,322 |
| average | | | | | | | |
| molecular | | | | | | | |
| weight | | | | | | | |
| (g/mol) | | | | | | | |

### Preparation Examples 9-13

Monomer (I), tert-butyl acrylate, catalyst (2,2′-azobis(2-methylpropionitrile, AIBN), chain transfer agent (1-dodecanethiol), and solvent (1-methoxy-2-propanol acetate, PGMEA) were mixed according to the proportions described in Table 2. The results were heated and stirred (reaction temperature and time as shown in Table 2), obtaining Polymers (8)-(12). The weight average molecular weight (Mw) of Polymers (8)-(12) was determined by gel permeation chromatography (GPC), and the results are shown in Table 2. The alkaline dissolution rate of Polymers (8) to (12) was evaluated, and the results are shown in Table 2. The method for evaluating alkaline dissolution rate was described as follows. The polymer was dissolved in PGMEA and the result was used to form a coating (with a thickness of 10 μm). After drying for 3 minutes, the coating was baked at 110° C. for 5 minutes and at 150° C. for 10 minutes, obtaining a film. Next, the thickness (T1) of the film was measured. Next, the film was immersed in a 1% sodium carbonate (Na₂CO₃) aqueous solution for 60 seconds. After removing and drying, the thickness (T2) of the film was measured. The alkaline dissolution rate was measured from the T1 and T2 values.

TABLE 2

| | Preparation | Preparation | Preparation | Preparation | Preparation |
|---|---|---|---|---|---|
| | Example | Example | Example | Example | Example |
| | 9_Polymer | 10_Polymer | 11_Polymer | 12_Polymer | 13_Polymer |
| | (8) | (9) | (10) | (11) | (12) |
| Monomer (I):tert- | 7:3 | 7:3 | 6:4 | 4:6 | 9:1 |
| butyl acrylate | | | | | |
| (molar ratio) | | | | | |
| total weight of | 234.5 | 234.5 | 219.3 | 188.9 | 264.8 |
| monomer (I) and | | | | | |
| tert-butyl | | | | | |
| acrylate (g) | | | | | |
| catalyst (g) | 6 | 3 | 3 | 3 | 4 |
| chain transfer | 12 | 1.5 | 1.5 | 3 | 4 |
| agent (g) | | | | | |
| solvent (g) | 275 | 265 | 258 | 240 | 300 |
| reaction | 90 | 90 | 90 | 90 | 90 |
| temperature | | | | | |
| (° C.) | | | | | |
| reaction time | 6 | 6 | 6 | 6 | 6 |
| (hours) | | | | | |
| weight average | 8,705 | 74,505 | 70,157 | 18,677 | 34,688 |
| molecular | | | | | |
| weight (g/mol) | | | | | |
| alkaline | 20 | 28 | 53 | 1 | 647 |
| dissolution rate | | | | | |
| (Å/s) | | | | | |

As shown in Table 2, due to the excessively high alkaline dissolution rate of Polymer (12), Polymer (12) was easily soluble in the developer solution. Therefore, it is not used for subsequent photoresist formulation validation.

### Preparation Example 14

Monomer (I), 1-ethylcyclohexyl methacrylate, catalyst (2,2′-azobis(2-methylpropionitrile, AIBN), chain transfer agent (1-dodecanethiol), and solvent (1-methoxy-2-propanol acetate, PGMEA) were mixed according to the proportions described in Table 3. The result was heated and stirred (reaction temperature and time as shown in Table 3), obtaining Polymer (13). The weight average molecular weight (Mw) of Polymer (13) was determined by gel permeation chromatography (GPC), and the results are shown in Table 3.

### Preparation Examples 15-17

Monomer (I), benzyl methacrylate (with a structure of

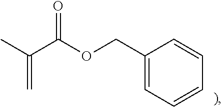

tert-butyl acrylate, catalyst (2,2′-azobis(2-methylpropionitrile, AIBN), chain transfer agent (1-dodecanethiol), and solvent (1-methoxy-2-propanol acetate, PGMEA) were mixed according to the proportions described in Table 3. The results were heated and stirred (reaction temperature and time as shown in Table 3), obtaining Polymers (14)-(16). The weight average molecular weight (Mw) of Polymers (14)-(16) was determined by gel permeation chromatography (GPC), and the results are shown in Table 3.

### Preparation Example 18

Monomer (I), styrene, 1-ethylcyclohexyl methacrylate, catalyst (2,2′-azobis(2-methylpropionitrile, AIBN), chain transfer agent (1-dodecanethiol), and solvent (1-methoxy-2-propanol acetate, PGMEA) were mixed according to the proportions described in Table 3. The result was heated and stirred (reaction temperature and time as shown in Table 3), obtaining Polymer (17). The weight average molecular weight (Mw) of Polymer (17) was determined by gel permeation chromatography (GPC), and the results are shown in Table 3.

TABLE 3

| | Preparation | | Preparation | Preparation | Preparation | | Preparation |
|---|---|---|---|---|---|---|---|
| | Example | | Example | Example | Example | | Example |
| | 14_Polymer | | 15_Polymer | 16_Polymer | 17_Polymer | | 18_Polymer |
| | (13) | | (14) | (15) | (16) | | (17) |
| | | Monomer | 6:1 | 6:1 | 6:1 | Monomer | 13:3 |
| | | (I):benzyl | | | | (I):styrene | |
| | | methacrylate | | | | (molar | |
| | | (molar | | | | ratio) | |
| | | ratio) | | | | | |
| Monomer | 7:3 | Monomer | 6:3 | 6:3 | 6:3 | Monomer | 13:4 |
| (I):1- | | (I):tert- | | | | (I):1- | |
| ethylcyclohexyl | | butyl | | | | ethylcyclohexyl | |
| methacrylate | | acrylate | | | | methacrylate | |
| (molar | | (molar | | | | (molar | |
| ratio) | | ratio) | | | | ratio) | |
| total | 254.8 | total | 224.1 | 224.1 | 224.1 | total | 236.8 |
| weight of | | weight of | | | | weight of | |
| Monomer (I) | | Monomer (I), | | | | Monomer (I), | |
| and 1- | | benzyl | | | | styrene, 1- | |
| ethylcyclohexyl | | methacrylate | | | | ethylcyclohexyl | |
| methacrylate | | and tert- | | | | methacrylate | |
| (g) | | butyl | | | | (g) | |
| | | acrylate | | | | | |
| | | (g) | | | | | |
| catalyst (g) | 3 | catalyst (g) | 3 | 3 | 4 | catalyst (g) | 4 |
| chain | 1.5 | chain | 1.5 | 3 | 3 | chain | 3 |
| transfer | | transfer | | | | transfer | |
| agent (g) | | agent (g) | | | | agent (g) | |
| solvent (g) | 276 | solvent (g) | 275 | 250 | 252 | solvent (g) | 265 |
| reaction | 90 | reaction | 90 | 90 | 90 | reaction | 90 |
| temperature | | temperature | | | | temperature | |
| (° C.) | | (° C.) | | | | (° C.) | |
| reaction | 6 | reaction | 6 | 6 | 6 | reaction | 6 |
| time | | time | | | | time | |
| (hours) | | (hours) | | | | (hours) | |
| weight | 91,746 | weight | 79,404 | 45,750 | 28,187 | weight | 68,619 |
| average | | average | | | | average | |
| molecular | | molecular | | | | molecular | |
| weight | | weight | | | | weight | |
| (g/mol) | | (g/mol) | | | | (g/mol) | |

### Preparation of Positive Photoresist Composition

### Examples 1-2 and Comparative Examples 1-6

Polymers (1) to (7) were individually mixed with photoacid generator (1,1,2,2,3,3,4,4,4-nonafluoro-1,3-dioxo-1H-benz [de]isoquinolin-2(3H)-yl ester), inhibitor (trioctylamine), and solvent (1,2-propylene glycol methyl ether acetate, PGMEA) according to the proportions described in Table 4. After uniform mixing, Positive photoresist compositions (1)-(8) were obtained.

TABLE 4

| | | polymer/ | photoacid | | |
|---|---|---|---|---|---|
| | | weight (g) | generator | inhibitor | solvent |
| Example 1 | Positive | Polymer | 6 | 3.30 | 317.5 |
| | photoresist | (1)/100 | | | |
| | composition | | | | |
| | (1) | | | | |
| Example 2 | Positive | Polymer | 6 | 3.30 | 317.5 |
| | photoresist | (7)/100 | | | |
| | composition | | | | |
| | (2) | | | | |
| Comparative | Positive | Polymer | 6 | 3.30 | 317.5 |
| Example 1 | photoresist | (2)/100 | | | |
| | composition | | | | |
| | (3) | | | | |
| Comparative | Positive | Polymer | 6 | 3.30 | 317.5 |
| Example 2 | photoresist | (3)/100 | | | |
| | composition | | | | |
| | (4) | | | | |
| Comparative | Positive | Polymer | 6 | 3.30 | 317.5 |
| Example 3 | photoresist | (4)/100 | | | |
| | composition | | | | |
| | (5) | | | | |
| Comparative | Positive | Polymer | 9 | 4.95 | 326.5 |
| Example 4 | photoresist | (4)/100 | | | |
| | composition | | | | |
| | (6) | | | | |
| Comparative | Positive | Polymer | 6 | 3.30 | 317.5 |
| Example 5 | photoresist | (5)/100 | | | |
| | composition | | | | |
| | (7) | | | | |
| Comparative | Positive | Polymer | 6 | 3.30 | 317.5 |
| Example 6 | photoresist | (6)/100 | | | |
| | composition | | | | |
| | (8) | | | | |

### Examples 3-9 and Comparative Example 7

Polymers (8) to (11) were individually mixed with photoacid generator (1,1,2,2,3,3,4,4,4-nonafluoro-1,3-dioxo-1H-benz [de]isoquinolin-2(3H)-yl ester), inhibitor (trioctylamine), and solvent (1,2-propylene glycol methyl ether acetate, PGMEA) according to the proportions described in Table 5. After uniform mixing, Positive photoresist compositions (9)-(16) were obtained.

TABLE 5

| | | polymer/ | photoacid | | |
|---|---|---|---|---|---|
| | | weight (g) | generator | inhibitor | solvent |
| Example 3 | Positive | Polymer | 6 | 3.3 | 317.5 |
| | photoresist | (9)/100 | | | |
| | composition | | | | |
| | (9) | | | | |
| Example 4 | Positive | Polymer | 9 | 4.95 | 326.5 |
| | photoresist | (9)/100 | | | |
| | composition | | | | |
| | (10) | | | | |
| Example 5 | Positive | Polymer | 12 | 6.6 | 335.5 |
| | photoresist | (9)/100 | | | |
| | composition | | | | |
| | (11) | | | | |
| Example 6 | Positive | Polymer | 6 | 3.3 | 317.5 |
| | photoresist | (10)/100 | | | |
| | composition | | | | |
| | (12) | | | | |
| Example 7 | Positive | Polymer | 9 | 4.95 | 326.5 |
| | photoresist | (10)/100 | | | |
| | composition | | | | |
| | (13) | | | | |
| Example 8 | Positive | Polymer | 6 | 3.3 | 317.5 |
| | photoresist | (11)/100 | | | |
| | composition | | | | |
| | (14) | | | | |
| Example 9 | Positive | Polymer | 9 | 4.95 | 326.5 |
| | photoresist | (11)/100 | | | |
| | composition | | | | |
| | (15) | | | | |
| Comparative | Positive | Polymer | 6 | 3.3 | 317.5 |
| Example 7 | photoresist | (8)/100 | | | |
| | composition | | | | |
| | (16) | | | | |

### Examples 10-17 and Comparative Example 8

Polymers (13) to (17) were individually mixed with phenol resin (with a weight average molecular weight about 11,000, commercially available from Sigma-Aldrich), photoacid generator (1,1,2,2,3,3,4,4,4-nonafluoro-1,3-dioxo-1H-benz [de]isoquinolin-2(3H)-yl ester), inhibitor (trioctylamine), and solvent (1,2-propylene glycol methyl ether acetate, PGMEA) according to the proportions described in Table 6. After uniform mixing, Positive photoresist compositions (17)-(25) were obtained.

TABLE 6

| | | polymer/ | photoacid | inhib- | sol- |
|---|---|---|---|---|---|
| | | weight (g) | generator | itor | vent |
| Example 10 | Positive | Polymer | 6 | 3.3 | 317.5 |
| | photoresist | (13)/100 | | | |
| | composition (17) | | | | |
| Example 11 | Positive | Polymer | 9 | 4.95 | 326.5 |
| | photoresist | (14)/100 | | | |
| | composition (18) | | | | |
| Example 12 | Positive | Polymer | 12 | 6.6 | 335.5 |
| | photoresist | (14)/100 | | | |
| | composition (19) | | | | |
| Example 13 | Positive | Polymer | 6 | 3.3 | 317.5 |
| | photoresist | (15)/100 | | | |
| | composition (20) | | | | |
| Example 14 | Positive | Polymer | 9 | 4.95 | 326.5 |
| | photoresist | (15)/100 | | | |
| | composition (21) | | | | |
| Example 15 | Positive | Polymer | 6 | 3.3 | 317.5 |
| | photoresist | (16)/100 | | | |
| | composition (22) | | | | |
| Example 16 | Positive | Polymer | 9 | 4.95 | 326.5 |
| | photoresist | (16)/100 | | | |
| | composition (23) | | | | |
| Example 17 | Positive | Polymer | 9 | 4.95 | 326.5 |
| | photoresist | (17)/100 | | | |
| | composition (24) | | | | |
| Comparative | Positive | phenol | 6 | 3.3 | 317.5 |
| Example 8 | photoresist | resin/100 | | | |
| | composition (25) | | | | |

### Preparation of Dry Film Photoresist Layer

Positive photoresist compositions (1)-(25) were individually coated onto a polyethylene terephthalate (PET) film by blade coating. After drying at 80° C. to remove the solvent, Dry film photoresist layers (1)-(25) with a thickness of about 6 μm were obtained. Next, a polyethylene terephthalate (PET) protective film was attached to the dry film photoresist layer.

### Transfer Printing Test

The dry film photoresist layer on the carrier film was cut into a sample (with a size of 7 cm*7 cm). After removing the protective film, the sample was attached to a wafer (10 cm*10 cm) and then the carrier film was subjected to pressure (about 2.5 kg/cm²) using a roller (with a roller temperature of 95° C. and a speed of 0.2 m/min) to transfer printing the dry film onto the wafer. After removing the carrier film, if the dry film was completely transferred to the wafer (with no residue left on the carrier film), it is marked with O. If the dry film is not completely transferred (with residue on the carrier film), it is marked with X. The results are shown in Table 7.

### Resolution Test

The transferred Dry film photoresist layers (1)-(25) were exposed to full spectrum ultraviolet light (with a line width of 2 μm and a line pitch of 2 μm). The exposed dry film was then developed with a sodium carbonate aqueous solution. The exposure dose, development time, and sodium carbonate aqueous solution concentration are listed in Table 7. If the developed dry film produces a pattern with a line width and pitch of 2 μm, it is marked with O; otherwise, it is marked with X. The results are shown in Table 7.

TABLE 7

| | | | | | sodium | |
|---|---|---|---|---|---|---|
| | | | | | carbonate | |
| | | | | | aqueous | |
| | | transfer | exposure | | solution | |
| | | printing | dose | development | concentration | resolution |
| | | test | (mJ/cm2) | time (sec) | (%) | test |
| Dry film | Positive | ◯ | 330 | 120 | 1 | ◯ |
| photoresist | photoresist | | | | | |
| layer (1) | composition (1) | | | | | |
| Dry film | Positive | ◯ | 800 | 90 | 1 | ◯ |
| photoresist | photoresist | | | | | |
| layer (2) | composition (2) | | | | | |
| Dry film | Positive | ◯ | 330 | 120 | 1 | X |
| photoresist | photoresist | | | | | |
| layer (3) | composition (3) | | | | | |
| Dry film | Positive | ◯ | 330 | 120 | 1 | X |
| photoresist | photoresist | | | | | |
| layer (4) | composition (4) | | | | | |
| Dry film | Positive | ◯ | 330 | 120 | 1 | X |
| photoresist | photoresist | | | | | |
| layer (5) | composition (5) | | | | | |
| Dry film | Positive | ◯ | 330 | 120 | 1 | X |
| photoresist | photoresist | | | | | |
| layer (6) | composition (6) | | | | | |
| Dry film | Positive | ◯ | 330 | 120 | 2 | X |
| photoresist | photoresist | | | | | |
| layer (7) | composition (7) | | | | | |
| Dry film | Positive | ◯ | 330 | 120 | 2 | X |
| photoresist | photoresist | | | | | |
| layer (8) | composition (8) | | | | | |
| Dry film | Positive | ◯ | 600 | 60 | 1 | ◯ |
| photoresist | photoresist | | | | | |
| layer (9) | composition (9) | | | | | |
| Dry film | Positive | ◯ | 600 | 60 | 1 | ◯ |
| photoresist | photoresist | | | | | |
| layer (10) | composition (10) | | | | | |
| Dry film | Positive | ◯ | 550 | 60 | 1 | ◯ |
| photoresist | photoresist | | | | | |
| layer (11) | composition (11) | | | | | |
| Dry film | Positive | ◯ | 550 | 90 | 1 | ◯ |
| photoresist | photoresist | | | | | |
| layer (12) | composition (12) | | | | | |
| Dry film | Positive | ◯ | 500 | 90 | 1 | ◯ |
| photoresist | photoresist | | | | | |
| layer (13) | composition (13) | | | | | |
| Dry film | Positive | ◯ | 550 | 90 | 1 | ◯ |
| photoresist | photoresist | | | | | |
| layer (14) | composition (14) | | | | | |
| Dry film | Positive | ◯ | 500 | 90 | 1 | ◯ |
| photoresist | photoresist | | | | | |
| layer (15) | composition (15) | | | | | |
| Dry film | Positive | ◯ | 330 | 120 | 1 | X |
| photoresist | photoresist | | | | | |
| layer (16) | composition (16) | | | | | |
| Dry film | Positive | ◯ | 500 | 90 | 1 | ◯ |
| photoresist | photoresist | | | | | |
| layer (17) | composition (17) | | | | | |
| Dry film | Positive | ◯ | 800 | 120 | 1 | ◯ |
| photoresist | photoresist | | | | | |
| layer (18) | composition (18) | | | | | |
| Dry film | Positive | ◯ | 700 | 120 | 1 | ◯ |
| photoresist | photoresist | | | | | |
| layer (19) | composition (19) | | | | | |
| Dry film | Positive | ◯ | 800 | 120 | 1 | ◯ |
| photoresist | photoresist | | | | | |
| layer (20) | composition (20) | | | | | |
| Dry film | Positive | ◯ | 600 | 90 | 1 | ◯ |
| photoresist | photoresist | | | | | |
| layer (21) | composition (21) | | | | | |
| Dry film | Positive | ◯ | 600 | 90 | 1 | ◯ |
| photoresist | photoresist | | | | | |
| layer (22) | composition (22) | | | | | |
| Dry film | Positive | ◯ | 450 | 90 | 1 | ◯ |
| photoresist | photoresist | | | | | |
| layer (23) | composition (23) | | | | | |
| Dry film | Positive | ◯ | 360 | 90 | 1 | ◯ |
| photoresist | photoresist | | | | | |
| layer (24) | composition (24) | | | | | |
| Dry film | Positive | X | 330 | 300 (unable | 1 | X |
| photoresist | photoresist | | | to develop) | | |
| layer (25) | composition (25) | | | | | |

As shown in Table 7, in comparison with conventional photosensitive phenol resin composition, the positive photoresist compositions (Examples 1-17), which include the polymer of the disclosure, can be developed using sodium carbonate aqueous solution, making them very suitable for use in printed circuit board processes. Additionally, when the polymer with the specific repeating unit of the disclosure has a weight average molecular weight lower than 14,000 g/mol, the resulting positive photoresist composition shows poor adhesion after exposure and development, making it unsuitable for forming patterns with a resolution of less than 10 μm (i.e., the composition is not suitable for forming low-resolution patterns). In addition, in comparison with conventional photosensitive phenol resin compositions, the positive photoresist compositions including the polymer of the disclosure can be developed using sodium carbonate aqueous solution, making them very suitable for use in printed circuit board processes.

Accordingly, due to the alkaline solubility of the polymer in the disclosure, it can be used in positive photoresist compositions to prepare high-resolution photosensitive positive dry films. The positive photoresist composition and the dry films prepared therefrom exhibits superior photosensitivity and light transmittance, enabling the creation of high clarity and high precision wiring patterns. Furthermore, due to good adhesion with the substrate during pattern formation and easy peelability after pattern formation, the process of forming wiring patterns is simplified.

It will be clear that various modifications and variations can be made to the disclosed methods and materials. It is intended that the specification and examples be considered as exemplary only, with the true scope of the disclosure being indicated by the following claims and their equivalents.

What is claimed is:

1. A polymer, comprising a first repeating unit and a second repeating unit, wherein the first repeating unit has a structure of Formula (I), and the second repeating unit has a structure of Formula (II) 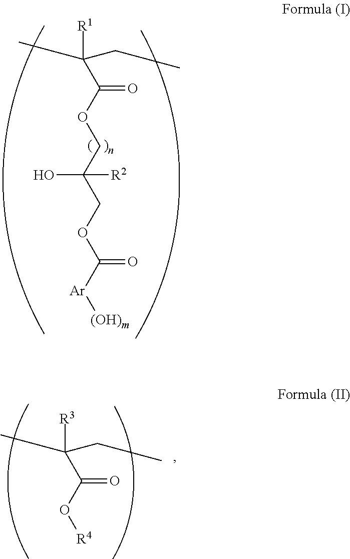
wherein R¹, R² and R³ are independently hydrogen or C1-C4 alkyl group; R⁴ is branched C4-C10 alkyl group, C5-C10 cycloalkyl group, or substituted C5-C10 cycloalkyl group; Ar is C6-C12 aryl group, or C7-C18 alkyl aryl group, wherein m number of hydrogen bonded with carbon of Ar is substituted by hydroxyl group; n is 0, 1, 2, 3, or 4; and m is 1, 2, or 3.

2. The polymer as claimed in claim 1, wherein the first repeating unit and the second repeating unit are arranged in a random or block fashion.

3. The polymer as claimed in claim 1, wherein a ratio of the first repeating unit to the second repeating unit is 100:20 to 100:150.

4. The polymer as claimed in claim 1, wherein the first repeating unit is 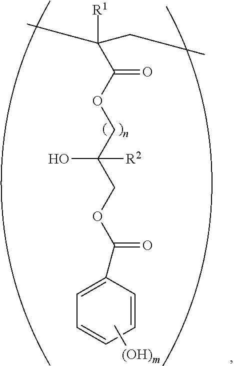
R¹ and R² are independently hydrogen or C1-C4 alkyl group; n is 0, 1, 2, 3, or 4; and m is 1, 2, or 3.

5. The polymer as claimed in claim 1, wherein the second repeating unit is 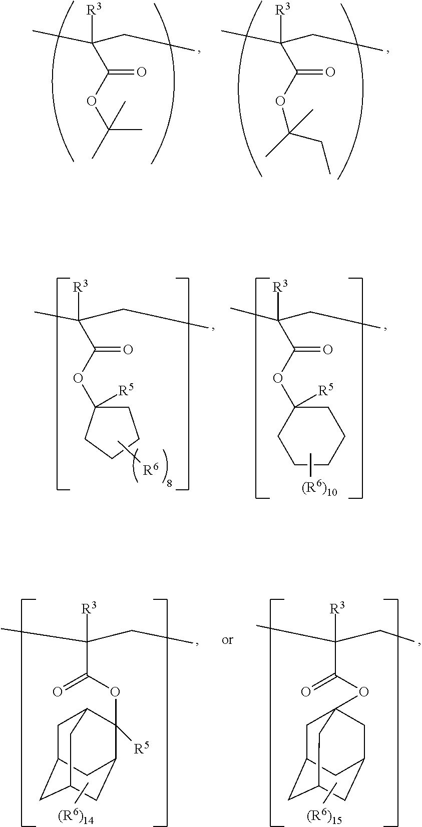
wherein R³ is hydrogen or C1-C4 alkyl group; R⁵ is C1-C4 alkyl group; and R⁶ is independently hydrogen, C1-C4 alkyl group, or hydroxyl group.

6. The polymer as claimed in claim 1, wherein the polymer further comprises a third repeating unit, wherein the third repeating unit has a structure of Formula (III) 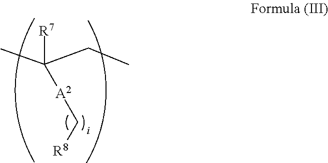
wherein R⁷ is hydrogen or C1-C4 alkyl group; A² is a single bond, or 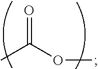
R⁸ is C6-C12 aryl group, or substituted C6-C12 aryl group; and i is 0, 1, 2, 3, or 4.

7. The polymer as claimed in claim 6, wherein a ratio of the first repeating unit to the third repeating unit is 100:1 to 100:50.

8. The polymer as claimed in claim 6, wherein the third repeating unit is 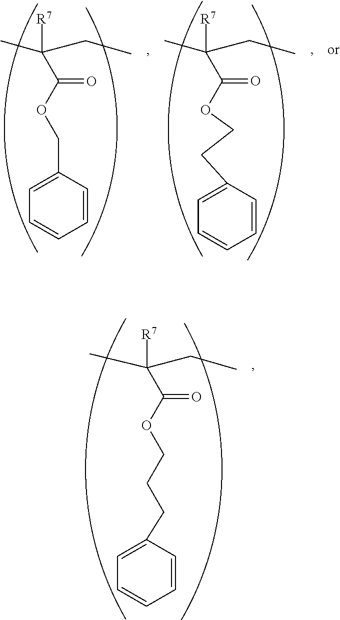
wherein R⁷ is hydrogen or C1-C4 alkyl group.

9. The polymer as claimed in claim 6, wherein the third repeating unit is 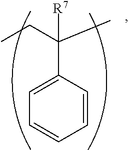
wherein R⁷ is hydrogen or C1-C4 alkyl group.

10. The polymer as claimed in claim 1, wherein a weight average molecular weight of the polymer is 14,000 g/mol to 100,000 g/mol.

11. A positive photoresist composition, comprising:
the polymer as claimed in claim 1; and
a photoacid generator.

12. The positive photoresist composition as claimed in claim 11, wherein the weight ratio of the photoacid generator to the polymer is 0.5:100 to 20:100.

13. The positive photoresist composition as claimed in claim 11, wherein the photoacid generator is an onium salt, triarylsulfonium salt, alkylarylsulfonium salt, diaryliodonium salt, diarylchloronium salt, diarylbromonium salt, sulfonate salt, sulfonate ester, fluorosulfonate ester, diazonium salt, diazonaphthoquinone sulfonate, or a combination thereof.

14. A method for forming a patterned photoresist layer, comprising:
subjecting a positive photoresist layer to an exposure process, wherein the positive photoresist layer is obtained by drying the positive photoresist composition as claimed in claim 11; and
subjecting the positive photoresist layer to a development process with a developer, obtaining a patterned photoresist layer.

15. The method for forming the patterned photoresist layer as claimed in claim 14, wherein the developer is an alkali metal salt aqueous solution, wherein the content of the alkali metal salt in the aqueous solution is 0.1 wt % to 5 wt %, based on a total weight of the alkali metal salt aqueous solution.
